(19) United States
(12) Patent Application Publication
(10) Pub. No.: US 2015/0371938 A1
(43) Pub. Date: Dec. 24, 2015

(54) BACK-END-OF-LINE STACK FOR A STACKED DEVICE

(71) Applicant: Invensas Corporation, San Jose, CA (US)

(72) Inventors: Rajesh Katkar, San Jose, CA (US); Liang Wang, Milpitas, CA (US); Charles G. Woychik, San Jose, CA (US); Hong Shen, Palo Alto, CA (US)

(73) Assignee: INVENSAS CORPORATION, San Jose, CA (US)

(21) Appl. No.: 14/309,703

(22) Filed: Jun. 19, 2014

(51) Int. Cl. H01L 23/528; H01L 21/683; H01L 23/00; H01L 25/065; H01L 25/00; H01L 23/522

(52) U.S. Cl. CPC H01L 23/528; H01L 25/50; H01L 23/5226; H01L 24/17; H01L 25/0655; H01L 21/6835; H01L 25/0657; H01L 2924/2064; H01L 2924/20641; H01L 2924/20642; H01L 2924/20643; H01L 2924/20644; H01L 2924/20645; H01L 2221/68359; H01L 2225/06513; H01L 2225/06548

(57) ABSTRACT

Apparatus relating generally to a back-end-of-line (“BEOL”) stack. In this apparatus, the BEOL stack is configured to electrically couple at least one first electrical component to at least one second electrical component. First contacts are provided on a first side of the BEOL stack with a first pitch for providing a bondable surface for connection to the at least one first electrical component. Second contacts are provided on a second side of the BEOL stack with a second pitch for providing another bondable surface for connection to the at least one second electrical component. The second pitch may be larger than the first pitch.

### FIELD

The following description relates to integrated circuits (“ICs”). More particularly, the following description relates to a Back-End-Of-Line stack for a stacked device.

### BACKGROUND

Microelectronic assemblies generally include one or more ICs, such as for example one or more packaged dies (“chips”) or one or more dies. One or more of such ICs may be mounted on a circuit platform, such as a wafer such as in wafer-level-packaging (“WLP”), printed board (“PB”), a printed wiring board (“PWB”), a printed circuit board (“PCB”), a printed wiring assembly (“PWA”), a printed circuit assembly (“PCA”), a package substrate, an interposer, or a chip carrier. Additionally, one IC may be mounted on another IC. An interposer may be an IC, and an interposer may be a passive or an active IC, where the latter includes one or more active devices, such as transistors for example, and the former does not include any active device. Furthermore, an interposer may be formed like a PWB, namely without any circuit elements such as capacitors, resistors, or active devices. Additionally, an interposer includes at least one through-substrate-via.

An IC may include conductive elements, such as pathways, traces, tracks, vias, contacts, pads such as contact pads and bond pads, plugs, nodes, or terminals for example, that may be used for making electrical interconnections with a circuit platform. These arrangements may facilitate electrical connections used to provide functionality of ICs. An IC may be coupled to a circuit platform by bonding, such as bonding traces or terminals, for example, of such circuit platform to bond pads or exposed ends of pins or posts or the like of an IC. Additionally, a redistribution layer (“RDL”) may be part of an IC to facilitate a flip-chip configuration, die stacking, or more convenient or accessible position of bond pads for example.

Interconnecting of an IC to another IC or to a circuit platform using an interposer has issues with respect to cost. Accordingly, it would be desirable and useful to provide a low cost alternative to use of an interposer.

### BRIEF SUMMARY

An apparatus relates generally to a back-end-of-line (“BEOL”) stack. In such an apparatus, the BEOL stack is configured to electrically couple at least one first electrical component to at least one second electrical component. First contacts are provided on a first side of the BEOL stack with a first pitch for providing a bondable surface for connection to the at least one first electrical component. Second contacts are provided on a second side of the BEOL stack with a second pitch larger than the first pitch, the second contacts providing another bondable surface for connection to the at least one second electrical component.

An apparatus relates generally to another BEOL stack. In such an apparatus, the BEOL stack is configured to electrically couple at least one first electrical component to at least one second electrical component. First contacts are provided on a first side of the BEOL stack with a first pitch for providing a bondable surface for connection to the at least one first electrical component. Second contacts are provided on a second side of the BEOL stack with a second pitch for providing another bondable surface for connection to the at least one second electrical component. Both the first pitch and the second pitch are fine pitches for interconnection with the at least one first electrical component and the at least one second electrical component, respectively.

A method relates generally to formation of a BEOL stack. In such a method, the BEOL stack is formed using a temporary support structure. The forming includes depositing dielectric layers and conductive layers with back-end-of-line dielectric and metal depositions. The conductive layers of the BEOL stack extend horizontally and vertically through the dielectric layers of the BEOL stack formed to provide electrically conductive paths. The BEOL stack includes first contacts of the conductive layers provided on a first side of the BEOL stack with a first pitch. The BEOL stack further includes second contacts of the conductive layers provided on a second side of the BEOL stack with a second pitch. The temporary support structure is removed after formation of the BEOL stack.

### BRIEF DESCRIPTION OF THE DRAWING(S)

Accompanying drawing(s) show exemplary embodiment(s) in accordance with one or more aspects of exemplary apparatus(es) or method(s). However, the accompanying drawings should not be taken to limit the scope of the claims, but are for explanation and understanding only.

FIG. 1-1 is a schematic diagram of a cross-sectional view depicting an exemplary portion of an in-process wafer for providing an integrated circuit (“IC”).

FIG. 1-2 is a schematic diagram of a cross-sectional view depicting an exemplary portion of an in-process wafer for providing another IC.

FIG. 1-3 is the diagram of FIG. 1-1 with the IC vertically flipped after chemical-mechanical-polishing of a lower surface of a substrate of the IC.

FIG. 1-4 is the diagram of FIG. 1-1 with the IC vertically flipped after a backside etch of a lower surface of a substrate of the IC to reveal a lower end contact surface of a via conductor thereof.

FIG. 1-5 is the diagram of FIG. 1-4 with a lower surface of the IC having formed thereon a passivation layer, which may be formed of one or more dielectric layers.

FIG. 2-1 is a block diagram of a cross-sectional view depicting an exemplary three-dimensional (“3D”) IC packaged component with via structures.

FIG. 2-2 is a block diagram of a cross-sectional view depicting another exemplary 3D IC packaged component with via structures.

FIGS. 3-1 through 3-8 are respective cross-sectional views for formation of a 3D stacked IC device without an interposer.

FIGS. 4-1 through 4-6 are respective cross-sectional views for formation of another 3D stacked IC device without an interposer.

FIGS. 5-1 through 5-3 are respective cross-sectional views for formation of a 3D stacked IC device without an interposer for platform-level dicing.

FIGS. 6-1 and 6-2 are respective cross-sectional views for formation of another 3D stacked IC device without an interposer for platform-level dicing.

FIG. 7 is a cross-sectional view depicting a 3D stacked IC device for dual-sided die attachment.

FIG. 8 is a cross-sectional view depicting a 3D stacked IC device including a the dual-sided die attachment of FIG. 7.

### DETAILED DESCRIPTION

In the following description, numerous specific details are set forth to provide a more thorough description of the specific examples described herein. It should be apparent, however, to one skilled in the art, that one or more other examples or variations of these examples may be practiced without all the specific details given below. In other instances, well known features have not been described in detail so as not to obscure the description of the examples herein. For ease of illustration, the same number labels are used in different diagrams to refer to the same items; however, in alternative examples the items may be different.

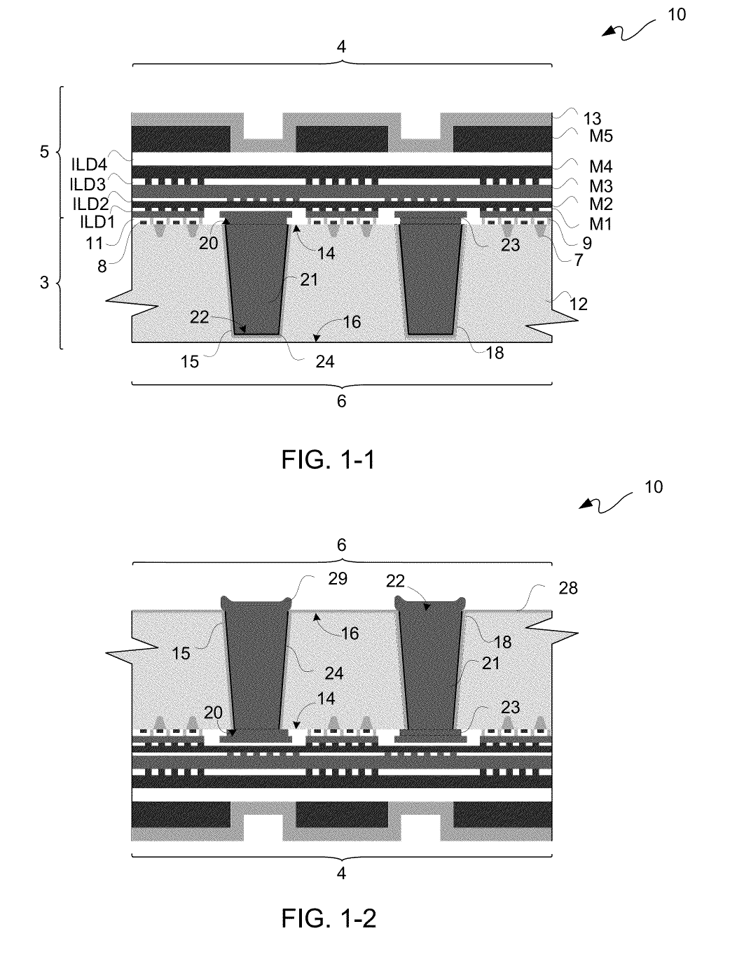

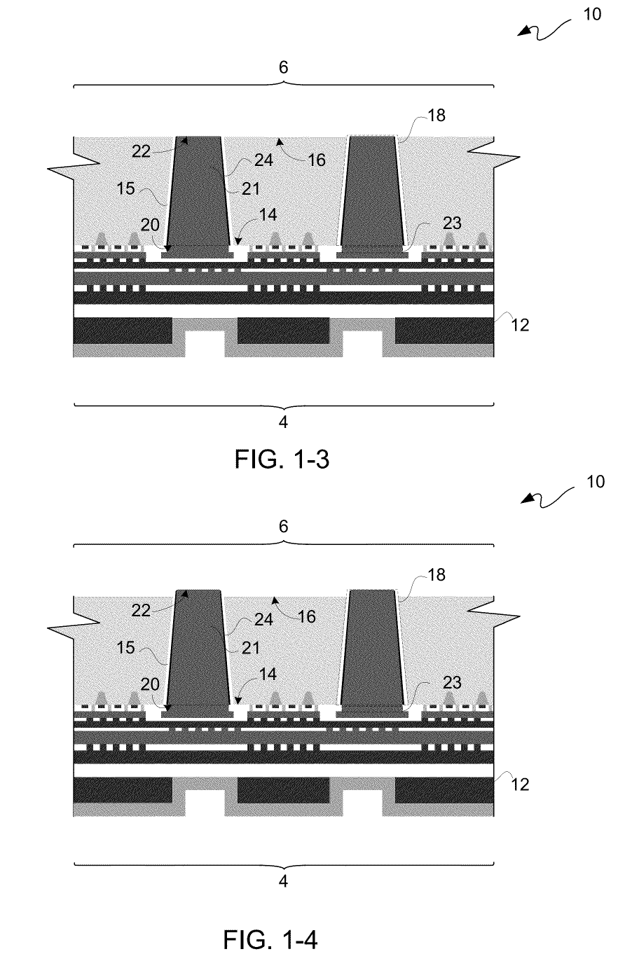

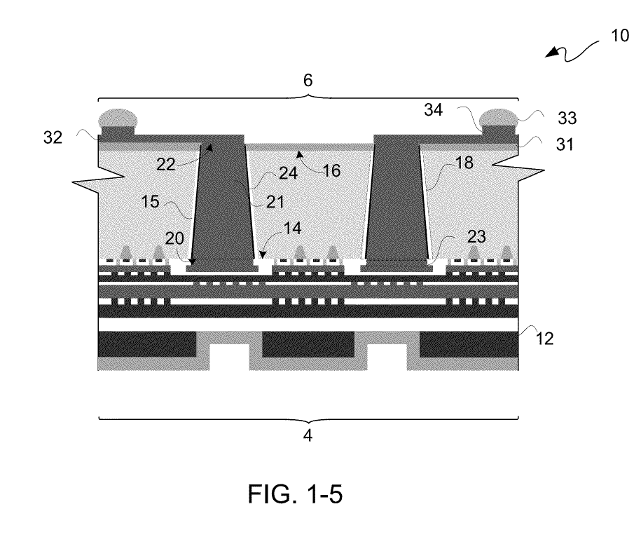

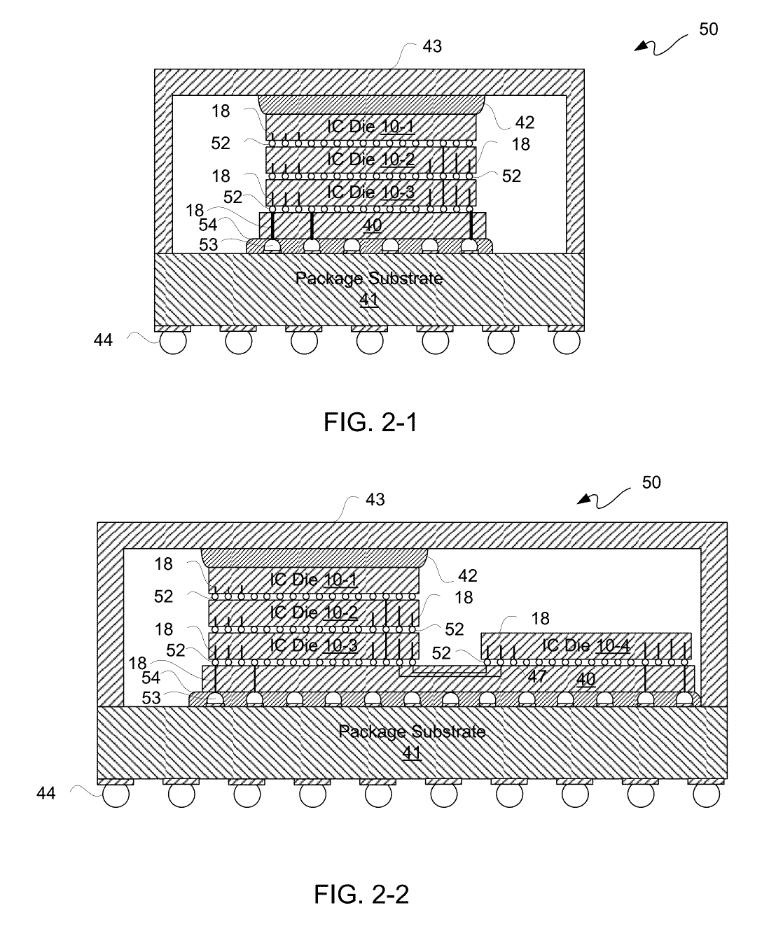

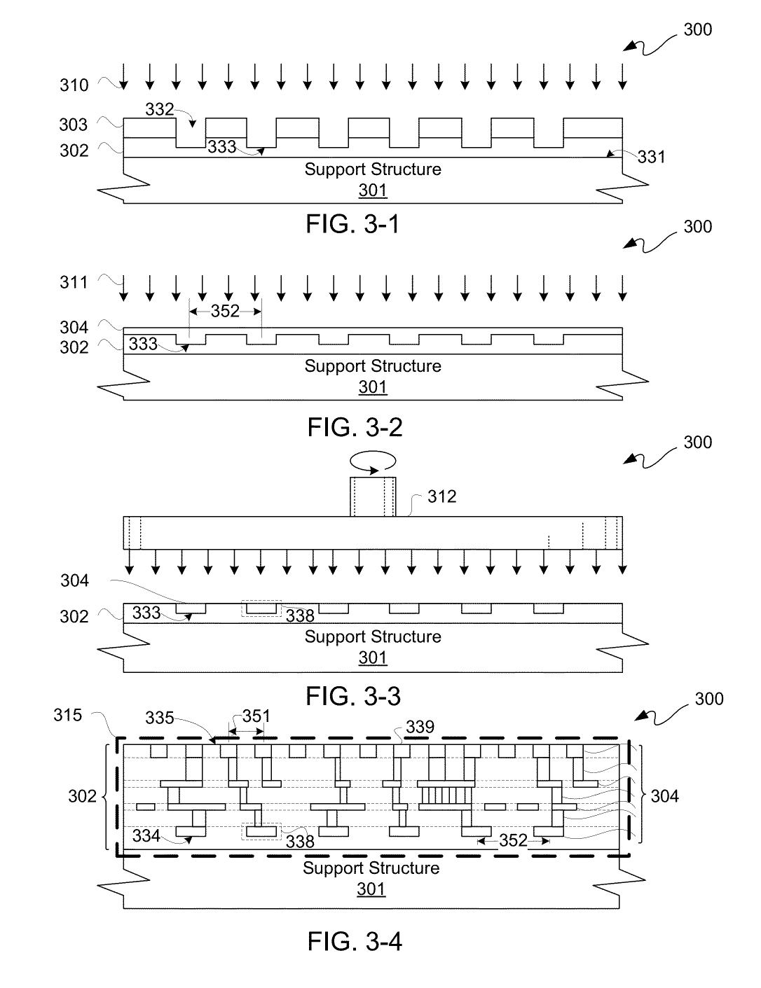

FIG. 1-1 is a schematic diagram of a cross-sectional view depicting an exemplary portion of an in-process wafer for providing an IC 10 component. IC 10 includes a substrate 12 of a semiconductor material such as silicon (Si), gallium arsenide (GaAs), polymeric, ceramic, carbon-based substrates such as diamond, a silicon carbon (SiC), germanium (Ge), Si₁₋ₓGeₓ, or the like. Even though a semiconductor substrate 12 as provided from an in-process wafer is generally described below, any sheet or layer semiconductor material or dielectric material, such as ceramic or glass for example, may be used as a substrate. Furthermore, even though an IC 10 is described, any microelectronic component that includes one or more through-substrate via structures may be used.

Substrate 12 includes an upper surface 14 and a lower surface 16 that extend in lateral directions and are generally parallel to each other at a thickness of substrate 12. Use of terms such as “upper” and “lower” or other directional terms is made with respect to the reference frame of the figures and is not meant to be limiting with respect to potential alternative orientations, such as in further assemblies or as used in various systems.

Upper surface 14 may generally be associated with what is referred to as a “front side” 4 of an in-process wafer, and lower surface 16 may generally be associated with what is referred to as a “backside” 6 of an in-process wafer. Along those lines, a front-side 4 of an in-process wafer may be used for forming what is referred to as front-end-of-line (“FEOL”) structures 3 and back-end-of-line (“BEOL”) structures 5. Generally, FEOL structures 3 may include shallow trench isolations (“STI”) 7, transistor gates 8, transistor source/drain regions (not shown), transistor gate dielectrics (not shown), contact etch stop layer (“CESL”; not shown), a pre-metallization dielectric or pre-metal dielectric (“PMD”) 11, and contact plugs 9, among other FEOL structures. A PMD 11 may be composed of one or more layers. Generally, BEOL structures 5 may include one or more inter-level dielectrics (“ILDs”) and one or more levels of metallization (“M”). In this example, there are four ILDs, namely ILD1, ILD2, ILD3, and ILD4; however, in other configurations there may be fewer or more ILDs. Furthermore, each ILD may be composed of one or more dielectric layers. In this example, there are five levels of metallization, namely M1, M2, M3, M4, and M5; however, in other configurations there may be fewer or more levels of metallization. Additionally, metal from a metallization level may extend through one or more ILDs, as is known. Furthermore, each level of metallization may be composed of one or more metal layers. A passivation level 13 may be formed on a last metallization layer. Such passivation level 13 may include one or more dielectric layers, and further may include an anti-reflective coating (“ARC”). Furthermore, a redistribution layer (“RDL”) may be formed on such passivation level. Conventionally, an RDL may include: a dielectric layer, such as a polyimide layer for example; another metal layer on such dielectric layer and connected to a bond pad of a metal layer of a last metallization level; and another dielectric layer, such as another polyimide layer for example, over such RDL metal layer while leaving a portion thereof exposed to provide another bond pad. A terminal opening may expose such other bond pad of such RDL metal layer. Thereafter, a solder bump or wire bond may be conventionally coupled to such bond pad.

As part of a FEOL or BEOL structure formation, a plurality of via structures 18 may extend within openings formed in substrate 12 which extend into substrate 12. Via structures 18 may be generally in the form of any solid of any shape formed by filling an opening formed in substrate 12. Examples of such solid shapes generally include cylindrical, conical, frustoconical, rectangular prismatic, cubic, or the like.

Conventionally, via structures 18 may extend from upper surface 14 down toward lower surface 16, and after a backside reveal, via structures 18 may extend between surfaces 14 and 16, as effectively thickness of substrate 12 may be thinned so as to reveal lower end surfaces of via structures 18, as described below in additional detail. Via structures 18 extending through substrate 12 between surfaces 14 and 16, though they may extend above or below such surfaces, respectively, may be referred to as through-substrate-vias. As substrates are often formed of silicon, such through-substrate-vias are commonly referred to as TSVs, which stands for through-silicon-vias.

Such openings formed in substrate 12 may be conformally coated, oxidized, or otherwise lined with a liner or insulator 15. Conventionally, liner 15 is silicon dioxide; however, a silicon oxide, a silicon nitride, or another dielectric material may be used to electrically isolate via structures 18 from substrate 12. Generally, liner 15 is an insulating or dielectric material positioned between any and all conductive portions of a via structure 18 and substrate 12 such that an electronic signal, a ground, a supply voltage, or the like carried by such via structure 18 is not substantially leaked into substrate 12, which may cause signal loss or attenuation, shorting, or other circuit failure.

Overlying a liner 15 may be a barrier layer 24. Generally, barrier layer 24 is to provide a diffusion barrier with respect to a metallic material used to generally fill a remainder of an opening in which a via structure 18 is formed. Barrier layer 24 may be composed of one or more layers. Furthermore, a barrier layer 24 may provide a seed layer for subsequent electroplating or other deposition, and thus barrier layer 24 may be referred to as a barrier/seed layer. Moreover, barrier layer 24 may provide an adhesion layer for adherence of a subsequently deposited metal. Thus, barrier layer 24 may be a barrier/adhesion layer, a barrier/seed layer, or a barrier/adhesion/seed layer. Examples of materials that may be used for barrier layer 24 include tantalum (Ta), tantalum nitride (TaN), palladium (Pd), titanium nitride (TiN), TaSiN, compounds of Ta, compounds of Ti, compounds of nickel (Ni), compounds of copper (Cu,), compounds of cobalt (Co), or compounds of tungsten (W), among others.

Via structures 18 may generally consist of a metallic or other conductive material generally filling a remaining void in an opening formed in substrate 12 to provide a via conductor 21. In various examples, a via conductor 21 of a via structure 18 may generally consist of copper or a copper alloy. However, a via conductor 21 may additionally or alternatively include one or more other conductive materials such as tantalum, nickel, titanium, molybdenum, tungsten, aluminum, gold, or silver, including various alloys or compounds of one or more of the these materials, and the like. A via conductor 21 may include non-metallic additives to control various environmental or operational parameters of a via structure 18.

Via structures 18 may each include an upper end contact surface 20 which may be level with upper surface 14 of substrate 12 and a lower end contact surface 22 which may be level with lower surface 16 of substrate 12 after a backside reveal. End surfaces 20 and 22 may be used to interconnect via structures 18 with other internal or external components, as below described in additional detail.

In this example, upper end contact surface 20 of via conductors 21 are interconnected to M1 through a respective contact pad 23. Contact pads 23 may be formed in respective openings formed in PMD 11 in which M1 extends. However, in other configurations, one or more via conductors 21 may extend to one or more other higher levels of metallization through one or more ILDs. Furthermore, via structure 18 is what may be referred to as a front side TSV, as an opening used to form via structure is initially formed by etching from a front side of substrate 12.

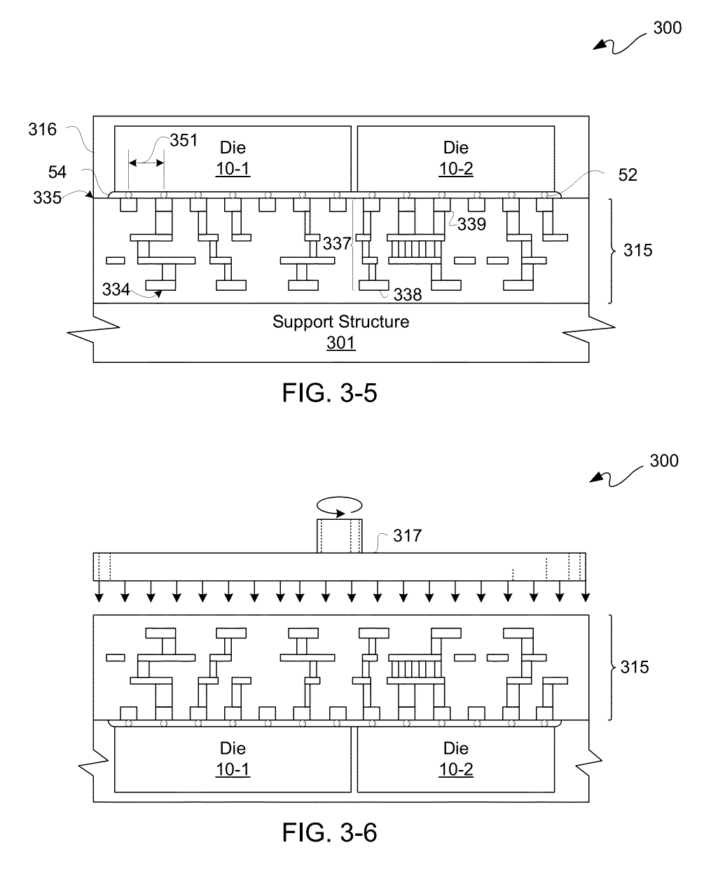

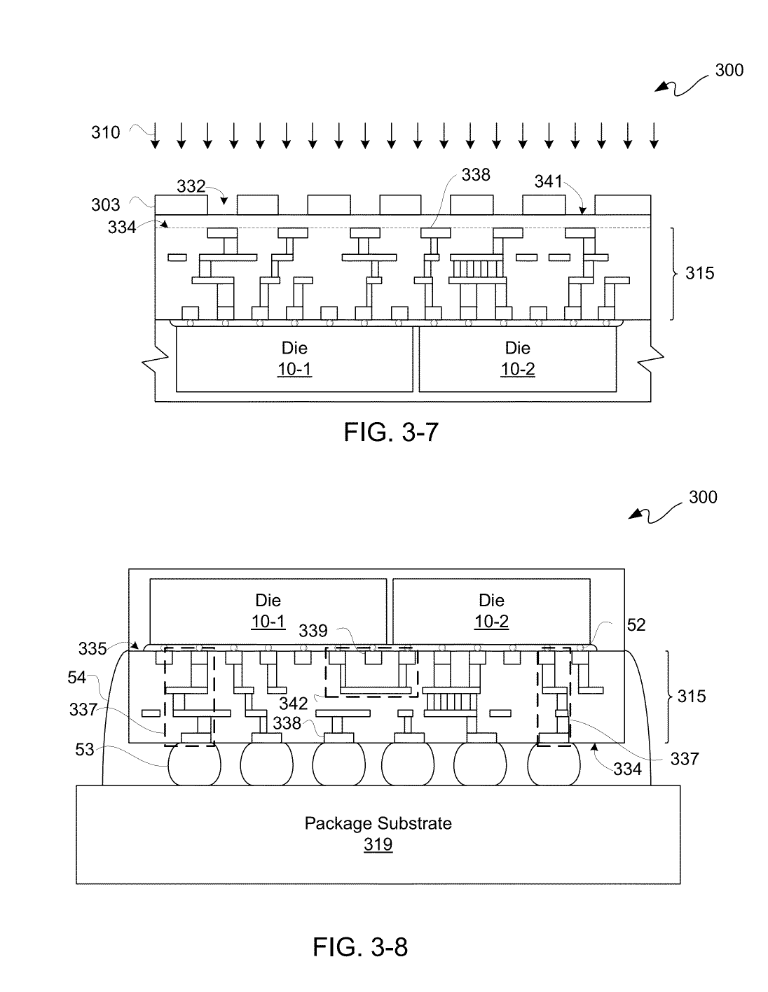

However, a via structure may be a backside TSV, as generally indicated in FIG. 1-2, where there is shown a schematic diagram of a cross-sectional view depicting an exemplary portion of an in-process wafer for providing another IC 10. Fabrication of a backside TSV is generally referred to as a “via last approach,” and accordingly fabrication of a front side TSV is generally referred to as a “via first approach.” Furthermore, a “via middle approach” may be used. A “via middle approach” is likewise a front side approach to via formation, but referred to as “middle” as vias are made after FEOL operations, but before BEOL operations.

IC 10 of FIG. 1-2 includes a plurality of via structures 18, which are backside TSVs. For a backside TSV for via structure 18, liner 15 may be a deposited polymer into a “donut” silicon trench etch and deposited on lower surface 16 as a passivation layer 28, followed by a central silicon trench etch to remove an inner portion of the “donut” silicon trench, and followed by a seed layer deposition before patterning and electroplating to provide via conductors 21 having respective solder bump pads or landings 29. Optionally, a conventional anisotropic silicon etch may be used prior to depositing and patterning a polymer isolation layer as liner 15.

For purposes of clarity by way of example and not limitation, it shall be assumed that front side TSVs are used, as the following description is generally equally applicable to backside TSVs.

FIG. 1-3 is the diagram of FIG. 1-1 with IC 10 after a chemical-mechanical-polishing (“CMP”) of a lower surface 16 of a substrate 12. Such CMP may be performed to temporarily reveal lower end contact surface 22, and thus portions of liner 15 and barrier layer 24 previously underlying lower end contact surface 22 may be removed by CMP. Thus, in this example, lower end contact surface 22 may be coplanar and level with lower surface 16.

FIG. 1-4 is the diagram of FIG. 1-1 with IC 10 after a backside etch of a lower surface 16 of substrate 12 to temporarily reveal a lower end contact surface 22 of a via conductor 21. In this example, lower end contact surface 22 may be coplanar with lower surface 16; however, as via conductor 21, and optionally barrier layer 24, may protrude from substrate 12 after a backside reveal etch, lower end contact surface 22 in this example is not level with lower surface 16. For purposes of clarity and not limitation, IC 10 of FIG. 1-4 shall be further described, as the following description may likewise apply to IC 10 of FIG. 1-3.

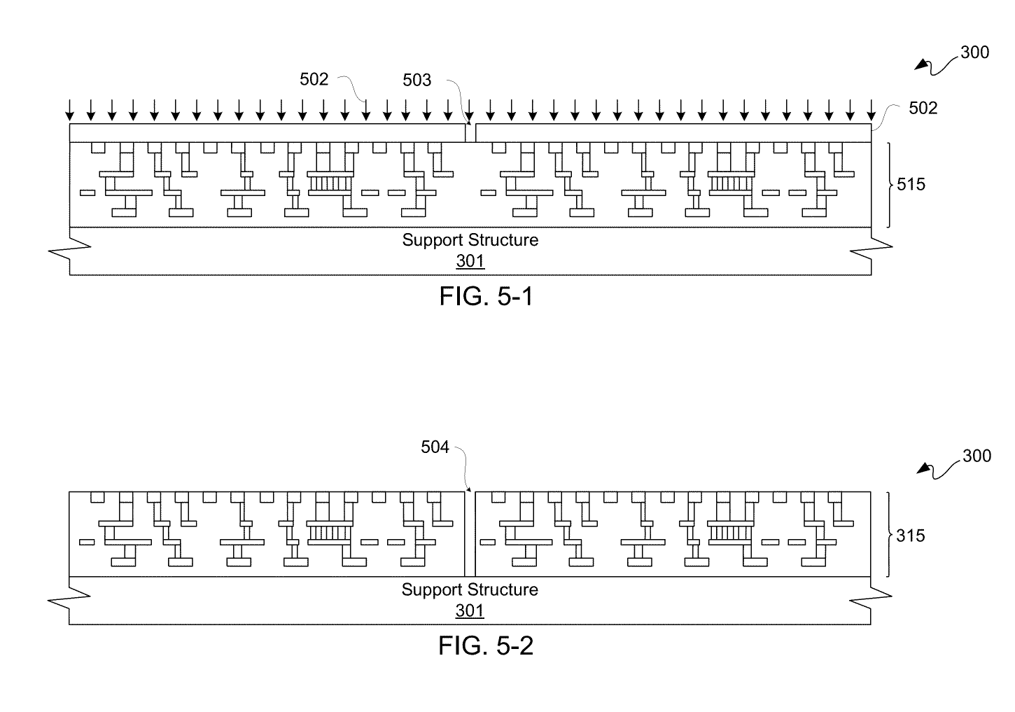

FIG. 1-5 is the diagram of FIG. 1-4 with a lower surface 16 of a substrate 12 having formed thereon a passivation layer 31, which may be formed of one or more dielectric layers. Furthermore, passivation layer 31 may be a polymer layer. For example, passivation layer 31 may be a benzocyclobutene (“BOB”) layer or a combination of a silicon nitride layer and a BCB layer or a polyimide layer. In some applications, passivation layer 31 may be referred to as an inter-die layer. A metal layer 32, such as a copper, copper alloy, or other metal previously described, may be formed on passivation layer 31 and on lower end contact surfaces 22 of via conductors 21. This metal layer 32 may be an RDL metal layer. Balls 33 may be respectively formed on bonding pads 34, where such pads may be formed on or as part of metal layer 32. Balls 33 may be formed of a bonding material, such as solder or other bonding material. Balls 33 may be microbumps, C4 bumps, ball grid array (“BGA”) balls, or some other die interconnect structure. In some applications, metal layer 32 may be referred to as a landing pad.

More recently, TSVs have been used to provide what is referred to as three-dimensional (“3D”) ICs or “3D ICs.” Generally, attaching one die to another using, in part, TSVs may be performed at a bond pad level or an on-chip electrical wiring level. ICs 10 may be diced from a wafer into single dies. Such single dies may be bonded to one another or bonded to a circuit platform, as previously described. For purposes of clarity by way of example and not limitation, it shall be assumed that an interposer is used for such circuit platform.

Interconnection components, such as interposers, may be in electronic assemblies for a variety of purposes, including facilitating interconnection between components with different connection configurations or to provide spacing between components in a microelectronic assembly, among others. Interposers may include a semiconductor layer, such as of silicon or the like, in the form of a sheet or layer of material or other substrate having conductive elements such as conductive vias extending within openings which extend through such layer of semiconductor material. Such conductive vias may be used for signal transmission through such interposer. In some interposers, ends of such vias may be used as contact pads for connection of such interposer to other microelectronics components. In other examples, one or more RDLs may be formed as part of such interposer on one or more sides thereof and connected with one or both ends of such vias. An RDL may include numerous conductive traces extending on or within one or more dielectric sheets or layers. Such traces may be provided in one level or in multiple levels throughout a single dielectric layer, separated by portions of dielectric material within such RDL. Vias may be included in an RDL to interconnect traces in different levels of such RDL.

FIG. 2-1 is a block diagram of a cross-sectional view depicting an exemplary 3D IC packaged component 50 with via structures 18. While a stacked die or a package-on-package die may include TSV interconnects, use of via structures 18 for a 3D IC packaged component 50 is described for purposes of clarity by way of example. In this example of a 3D IC packaged component 50, there are three ICs 10, namely ICs 10-1, 10-2, and 10-3, stacked one upon the other. In other implementations, there may be fewer or more than three ICs 10 in a stack. ICs 10 may be bonded to one another using microbumps 52 or flip-chip solder bumps. Optionally, Cu pillars extending from a backside of a die may be used. Some of these microbumps 52 may be interconnected to via structures 18. For example, a Cu/Sn microbump transient liquid phase (“TLP”) bonding or thermal compressive Cu—Cu bonding technology may be used for bonding ICs to one another. Thus, interconnect layers may be on one upper or lower side or both upper and lower sides of an IC 10 of a 3D stack.

A bottom IC 10-3 of such ICs in a 3D stack optionally may be coupled to an interposer or interposer die 40. Interposer 40 may be an active die or a passive die. For purposes of clarity and not limitation, it shall be assumed that interposer 40 is a passive die. IC 10-3 may be coupled to interposer 40 by microbumps 52. Interposer 40 may be coupled to a package substrate 41. Package substrate 41 may be formed of thin layers called laminates or laminate substrates. Laminates may be organic or inorganic. Examples of materials for “rigid” package substrates include an epoxy-based laminate such as FR4, a resin-based laminate such as bismaleimide-triazine (“BT”), a ceramic substrate, a glass substrate, or other form of package substrate. An under fill 54 for a flip chip attachment may encapsulate C4 bumps or other solder balls 53 used to couple interposer 40 and package substrate 41. A spreader/heat sink (“heat sink”) 43 may be attached to package substrate 41, and such heat sink 43 and substrate package 41 in combination may encase ICs 10 and interposer 40 of such 3D stack. A thermal paste 42 may couple an upper surface of IC 10-1 on top of such 3D stack to an upper internal surface of such heat sink 43. Ball grid array (“BGA”) balls or other array interconnects 44 may be used to couple package substrate 41 to a circuit platform, such as a PCB for example.

FIG. 2-2 is a block diagram of a cross-sectional view depicting another exemplary 3D IC packaged component 50 with via structures 18. 3D IC packaged components 50 of FIGS. 2-1 and 2-2 are the same except for the following differences; in FIG. 2-2, another IC 10-4 is separately coupled via microbumps 52 to interposer 40, where IC 10-4 is not coupled in the stack of ICs 10-1, 10-2, and 10-3. Furthermore, interposer 40 includes metal and via layers for providing wires 47 for interconnecting ICs 10-3 and 10-4. Furthermore, interposer 40 includes via structures 18 coupled to IC 10-4 through microbumps 52.

3D wafer-level packaging (“3D-WLP”) may be used for interconnecting two or more ICs, one or more ICs to an interposer, or any combination thereof, where interconnects thereof may use via structures 18. Optionally, ICs may be interconnected die-to-die (“D2D”) or chip-to-chip (“C2C”), where interconnects thereof may use via structures 18. Further, optionally, ICs may be interconnected die-to-wafer (“D2W”) or chip-to-wafer (“C2W”), where interconnects thereof may use via structures 18. Accordingly, any of a variety of die stacking or chip stacking approaches may be used to provide a 3D stacked IC (“3D-SIC” or “3D-IC”).

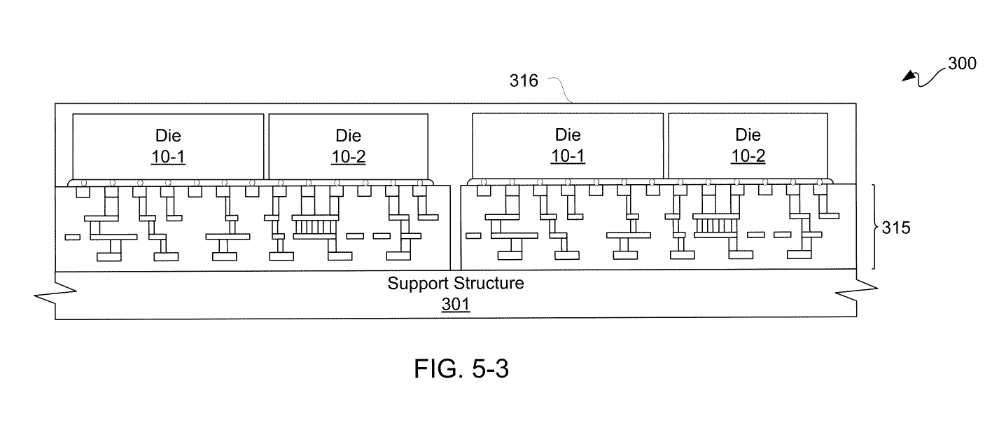

FIGS. 3-1 through 3-8 are respective cross-sectional views for formation of a 3D stacked IC device 300 without an interposer. A temporary support structure 301 is obtained. Such support structure 301 may be a blank or an interposer or other removable platform, such as of a wafer for wafer-level formation for example. For purposes of clarity by way of example and not limitation, it shall be assumed that support structure 301 is a silicon wafer. A silicon wafer may be reused for other formations, as will be apparent from the following description.

A dielectric layer 302 is grown or deposited or a combination thereof on an upper surface 331 of support structure 301. For example, a full-thickness silicon wafer may be used to grow a thermal oxide to provide a dielectric layer 302. A masking layer 303, such as a resist, is deposited and patterned on dielectric layer 302. Masking layer 303 is patterned to define openings 332 in masking layer 303 exposing corresponding portions of an upper surface of dielectric layer 302. A dielectric etch 310 operation, which may be a wet or dry etch, is performed to etch recesses 333 into dielectric layer 302 through openings 332. Dielectric etch 310 may be an anisotropic etch.

Masking layer 303 may be removed, and one or more metal or other conductive layers (“metal layer 304”) may be deposited on an upper surface of dielectric layer 302, including into recesses formed therein, with a metal deposition 311 operation. Recesses 333 formed in dielectric layer 302 may be on a pitch 352, as described below in additional detail.

An upper portion of metal layer 304 may be removed by a metal etch or a CMP 312 operation. A lower portion of metal layer 304 may remain in recesses 333 after such a CMP 312 operation to provide conductive pads, traces, contracts, and/or other conductive structures (“contacts”) 338, whether generally horizontal or vertical conductive structures.

Operations as described with reference to FIGS. 3-1 through 3-3 may generally be repeated corresponding to BEOL processing, though with a placeholder support structure 301, to provide a BEOL stack 315.

After such BEOL processing, a BEOL stack 315 may be provided having a plurality of dielectric layers 302 and a plurality of metal layers 304. A lower surface, generally surface 334, of a lowermost set of conductive structures of a BEOL stack 315 may resemble a bondable backside surface, such as for example a surface with under bump metallization pads or bond pads as contacts 338. An uppermost or top surface 335 of such a BEOL stack 315 may resemble a bondable front side surface of an interposer die, such as for example a surface having contacts 339 used to mount to a die using microbumps or other fine pitch contacts.

Contacts 339 may be provided on an upper side 335 of BEOL stack 315 with a pitch 351. In an implementation, pitch 351 may be less than approximately 100 microns. Generally, by “fine pitch” it is meant a pitch of less than approximately 100 microns. More particularly, in some implementations, a “fine pitch” may be less than approximately 60 microns. Contacts 338 provided on a lower side of BEOL stack 315 may have a pitch 352, where pitch 351 of contacts 339 is less than pitch 352 of contacts 338. In an implementation, pitch 352 of contacts 338 may be greater than approximately 50 microns and less than approximately 500 microns. Along those lines, there may be multiples of tens of thousands of contacts 339, while there may be multiples of thousands of contacts 338.

Conductive metal layers 304 of BEOL stack 315 may extend horizontally and/or vertically through insulating layers 302 of BEOL stack 315 for providing various interconnections to and between contacts 338 and 339. Along those lines, a portion of conductive metal layers 304 may be interconnected to one another to provide electrically conductive paths, such as conductive path 337 for example, from a portion of contacts 339 on upper side 335 of BEOL stack 315 to contacts 338 on a lower side 334 of BEOL stack 315. Electrically conductive paths 337 may be used to interconnect at least two electrical components, such as for example integrated circuit dies 10-1 and 10-2, via a portion of contacts 339 to upper side 335 of BEOL stack 315 via microbumps 52 or flip-chip solder bumps. Again, micro bumps 52 may be for a pitch 351. An under fill 54 may be injected under microbumped integrated circuit dies 10-1 and 10-2 followed by depositing or molding an encapsulant 316. Electrically conductive paths 337 may be used to interconnect a circuit platform via contacts 338 to a lower side 334 of BEOL stack 315 after removal of support structure 301, as described below in additional detail.

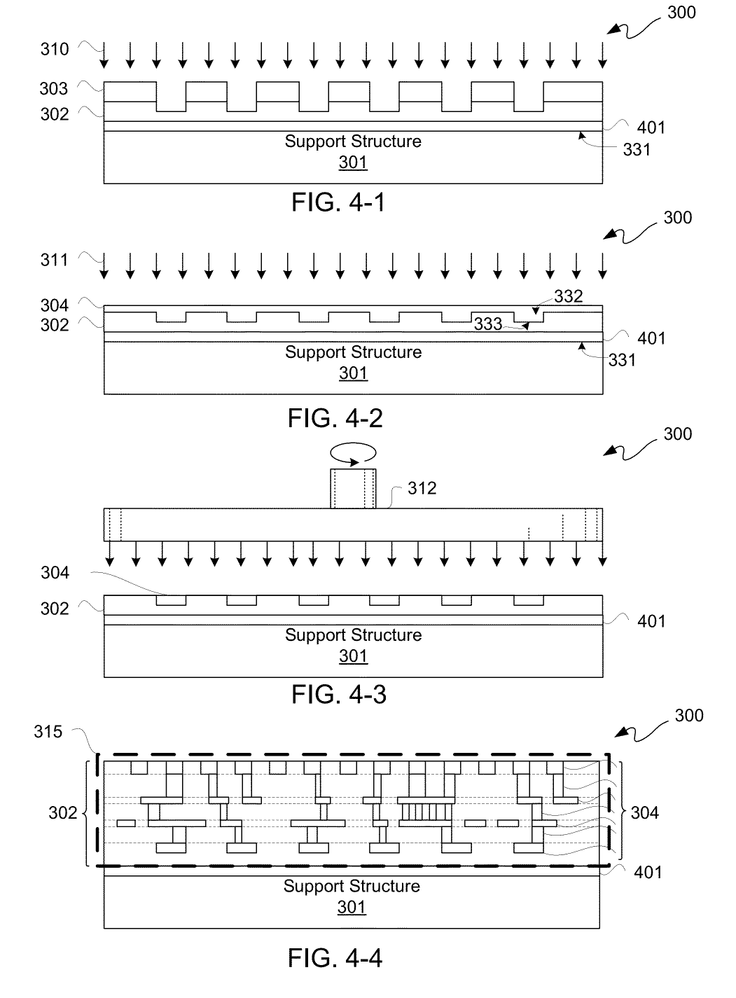

With particular reference to FIG. 3-6, support structure 301 may be removed, as support structure 301 is not in the finished product. Support structure 301 may be removed by a CMP 317 operation as illustratively depicted, or by grinding, dry reactive ion etching, lift-off, or other removal means, or a combination of two or more of these. An initial dielectric layer 302 may be used as a stop layer, such as an etch stop layer, CMP stop layer, or grind stop layer. After removal of support structure 301, a BEOL stack 315, namely a stack without a substrate, may be provided with a configuration to provide an interposer-like functionality for a stacked die assembly, such as a 3D stacked IC device 300. Optionally, CMP 317 may be changed in situ after removing support structure 301 to remove a lowermost portion of an initial dielectric layer 302 of BEOL stack 315.

After removal of support structure 301, a lowermost portion of an initial dielectric layer 302 may be removed by a CMP operation as previously described, or other material removal operation for exposing lower surface 334 to expose lower surfaces of contacts 338. With respect to the latter, the mask used to pattern masking layer 303 may be used to expose lower surfaces 334 of contacts 338. Along those lines, another masking layer 303 may be deposited and patterned on a lower surface 341 of BEOL stack 315 to define another set of openings 332. Another dielectric etch 310 may be used to form opening down to lower surfaces 334 of contacts 338.

Contacts 338 may be coupled to a package substrate 319, or other circuit platform. In the example of FIG. 3-8, lower surfaces 334 of contacts 338 have been exposed by CMP 317. C4 bumps or other solder balls 53 are used to interconnect package substrate 319 to contacts 338 of BEOL stack 315. An under fill 54 may be injected under, and along sides, of BEOL stack 315. Conductive paths 337 extending from lower surface 334 to upper surface 335 of BEOL stack 315 may interconnect C4 bumps or other solder balls 53 to microbumps 52 for electrical communication between integrated circuit dies 10-1 and 10-2 with package substrate 319. Moreover, a portion of conductive layers 304 may be interconnected to one another to provide electrically conductive paths, such as conductive path 342, from a portion of contacts 339 on an upper side 335 of BEOL stack 315 to another portion of contacts 339 on upper side 335 of BEOL stack 315 to interconnect at least two integrated circuit dies, such as integrated circuit dies 10-1 and 10-2 for example, to one another via such portions of contacts 339 as well as to such upper side 335 of BEOL stack 315.

FIGS. 4-1 through 4-6 are respective cross-sectional views for formation of another 3D stacked IC device 300 without an interposer. As FIGS. 4-1 through 4-6 respectively generally correspond to the description of FIGS. 3-1 through 3-6, generally only the differences are described below for purposes of clarity. FIGS. 4-1 through 4-6 are for a lift-off of support substrate 301.

A support structure 301 is obtained. For this implementation, such support structure 301 may be a transparent carrier, such as a glass, quartz, sapphire, or other transparent material.

A sacrificial layer 401, such as less than approximately 100 nm thick, is deposited on upper surface 331 of support structure 301. Such sacrificial layer 401 may be GaN, InN, or other readily removable layer in accordance with the following description. Such sacrificial layer 401 may be deposited with CVD, sputtering, e-beam evaporation, or other type of deposition.

A dielectric layer 302 is deposited on sacrificial layer 401. This first or initial dielectric layer 302 may be one from which sacrificial layer 401 is more easily removed for a laser lift-off, such as a SiN layer for example. Optionally, a GaN sacrificial layer 401 may additionally provide an initial dielectric layer 302, which is patterned as described below in additional detail. Thus, a laser lift-off may be used to remove a thin layer of GaN while leaving a portion of GaN in place as a dielectric layer 302. Optionally, a GaN initial dielectric layer 302 may be entirely removed during lift-off to leave metal contacts 338 exposed.

A masking layer 303, such as a resist, is deposited and patterned on dielectric layer 302. Masking layer 303 is patterned to define openings 332 in masking layer 303 exposing corresponding portions of an upper surface of dielectric layer 302. A dielectric etch 310 operation, which may be a wet or dry etch, is performed to etch recesses 333 into dielectric layer 302 through openings 332. Dielectric etch 310 may be an anisotropic etch. The above description up to removal of support structure 301 is the same for both sets of FIGS. 3-1 through 3-5 and 4-1 through 4-5.

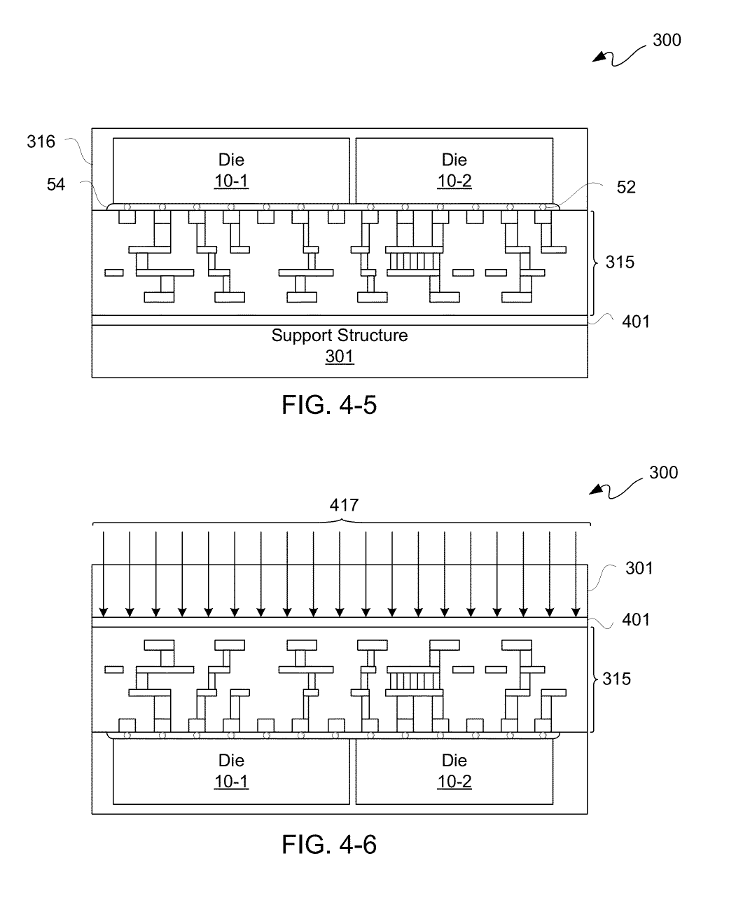

With particular reference to FIG. 4-6, support structure 301 may be removed by providing energy 417 through support structure 301 to sacrificial layer 401. For example, energy 417 may be provided with a laser. For the above example, as support structure 301 is transparent, laser light energy 417 may decompose a thin layer of GaN or InN into Ga or In and N, where Ga or In is decomposed into a liquid form at a low temperature, approximately 40° C. At which point, support structure 301 may be mechanically separated from BEOL stack 315, with any residual liquid from such decomposition being cleaned off of BEOL stack 315. Support structure 301 may thereafter be cleaned for reuse. After which, the assembly of FIG. 4-6 may be subsequently packaged as previously described with reference to FIG. 3-8 and not repeated here for purposes of clarity.

FIGS. 5-1 through 5-3 are respective cross-sectional views for formation of a 3D stacked IC device 300 without an interposer for platform-level dicing. For purposes of clarity by way of example and not limitation, it shall be assumed that a 300 mm or 12 inch wafer is used for support structure 301. Therefore, the large wafer may be subject to cracking level stressors during wafer-level packaging, which cracks may propagate through such a wafer. Along those lines, stress relief scribe lanes or street lines may be created to reduce such possibility.

A masking layer 502 is deposited and patterned on a multi-BEOL stack 515 to define one or more recesses 503 associated with stress relief scribe lanes or street lines. A dielectric etch 502 is used to etch an opening through dielectric layers 302 between BEOL stacks 315 of multi-BEOL stack 515 to form an opening or trench 504. Dielectric etch 502 in this example is a stop on material of support substrate 301 etch, such as a stop on silicon dielectric etch for the example of a silicon wafer as a support structure 301. Opening 504 may be used to delineate BEOL stacks 315 of a multi-BEOL stack 515.

Respective sets of integrated circuit dies, or other suitable dies, may be interconnected to each of BEOL stacks 315 of a multi-BEOL stack 515 while such BEOL stacks 315 are attached to a same support structure 301. Continuing the above example, pairs of integrated circuit dies 10-1 and 10-2 are respectively interconnected to BEOL stacks 315 through corresponding sets of microbumps followed by injection of an under fill, such as previously described. An encapsulation, such as by depositing or molding an encapsulant 316, may be used to encapsulate each of such pairs of integrated circuit dies 10-1 and 10-2 in a same operation, namely wafer-level encapsulation.

Additionally, even though it has been assumed that two or more integrated circuit or other dies are interconnected to a BEOL stack 315, in other configurations a single integrated circuit die may be attached to a BEOL stack 315. For example, a BEOL stack 315 may be formed independently from a large integrated circuit die to reduce the number of BEOL operations used in forming such a large integrated circuit die. This may improve yield of such large integrated circuit die by avoiding many BEOL operations, which operations may effectively be transferred to formation of a BEOL stack 315. Such BEOL stack 315 may be substantially less expensive to manufacture than a large integrated circuit die, and accordingly such BEOL stack 315 may be tested prior to interconnection to any integrated circuit die. Thus, complications associated with BEOL operations of an integrated circuit die may be removed from fabrication of such integrated circuit die. Moreover, if formation of BEOL layers increases a die's size, then removing BEOL operations of an integrated circuit die to a BEOL stack may increase the number of integrated circuit dies per wafer.

FIGS. 6-1 and 6-2 are respective cross-sectional views for formation of another 3D stacked IC device 300 without an interposer for platform-level dicing. FIGS. 6-1 and 6-2 correspond to FIGS. 5-2 and 5-3, and so corresponding description is generally not repeated for purposes of clarity, though FIGS. 6-1 and 6-2 are further described with simultaneous reference to FIGS. 5-1 through 5-3. Support structure 301 may be subsequently removed, such as previously described.

In FIGS. 6-1 and 6-2, opening 504 is formed as previously described, but rather than a stop on support substrate 301 dielectric etch 502, etch 502 may be changed in situ. Thus, after etch 502 etches through all dielectric layers 302 of multi-BEOL stack 515, chemistry of etch 502 may be change in situ to partially etch into support structure 301. Thus, opening 504 may extend through all dielectric layers 302 of multi-BEOL stack 515 and extend into a portion of support structure 301. Support structure 301 may be subsequently removed, such as previously described.

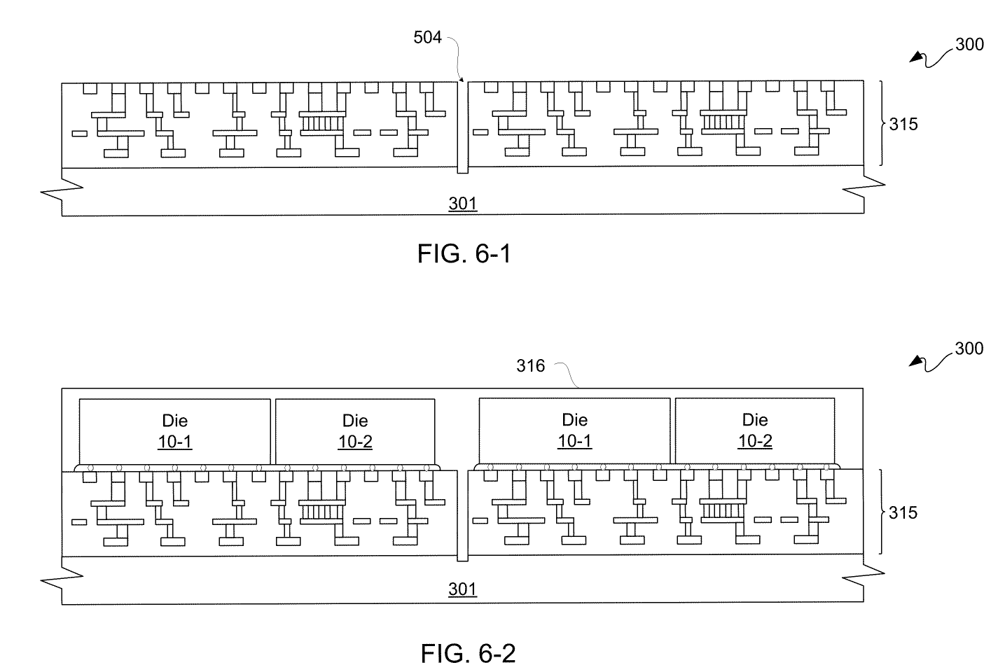

FIG. 7 is a cross-sectional view depicting a 3D stacked IC device 300 for dual-sided die attachment. In this configuration, a BEOL stack 315-1 is formed with fine pitch contacts 339 on both an upper surface 335 and lower surface 334 thereof. In this example, contacts 339 on both upper surface 335 and lower surface 334 have at least an approximately equal pitch 351 for interconnection with respective sets of integrated circuit dies. More generally, each of pitches 351 on opposing sides of BEOL stack 315-1 is less than approximately 60 microns for these fine pitches.

In this example, integrated circuit dies 10-1 and 10-2 are interconnected to a lower surface 334 of BEOL stack 315-1 with corresponding microbumps 52, under fill 54, and encapsulant 316, and integrated circuit dies 10-3 and 10-4 are interconnected to an upper surface 335 of BEOL stack 315-1 with corresponding microbumps 52, under fill 54, and encapsulant 316. Even though pairs of integrated circuit dies are illustratively depicted on opposing sides of BEOL stack 315-1, either or both of such opposing sides may have one or more integrated circuit dies interconnected respectively thereto.

BEOL stack 315-1 may include horizontal conductive paths 342 for interconnection of dies 10-1 and 10-2, as well as horizontal conductive paths 342 for interconnection of dies 10-3 and 10-4. Likewise, BEOL stack 315-1 may include vertical conductive paths 337 for interconnection of dies 10-1 and 10-3, as well as vertical conductive paths 337 for interconnection of dies 10-2 and 10-4. These are just some examples of die-to-die interconnections on a same side and on opposing sides of BEOL stack 315-1, and other such interconnections may be used.

For this 3D stacked IC device 300 for dual-sided die attachment, temporary support structure 301 is left in place for coupling of integrated circuit dies 10-3 and 10-4, such as previously described with reference to FIG. 3-5 with respect to coupling of integrated circuit dies 10-1 and 10-2. Then, temporary support structure 301 may be removed, such as previously described, where integrated circuit dies 10-3 and 10-4, whether encapsulated or not, may be used to provide the support previously provided with support structure 301 for coupling of integrated circuit dies 10-1 and 10-2. In other words, after coupling of integrated circuit dies 10-3 and 10-4 to an upper surface 335 of BEOL stack 315-1 with microbumps 52, integrated circuit dies 10-1 and 10-2 may be coupled to a lower surface 334 of BEOL stack 315-1 such as previously described.

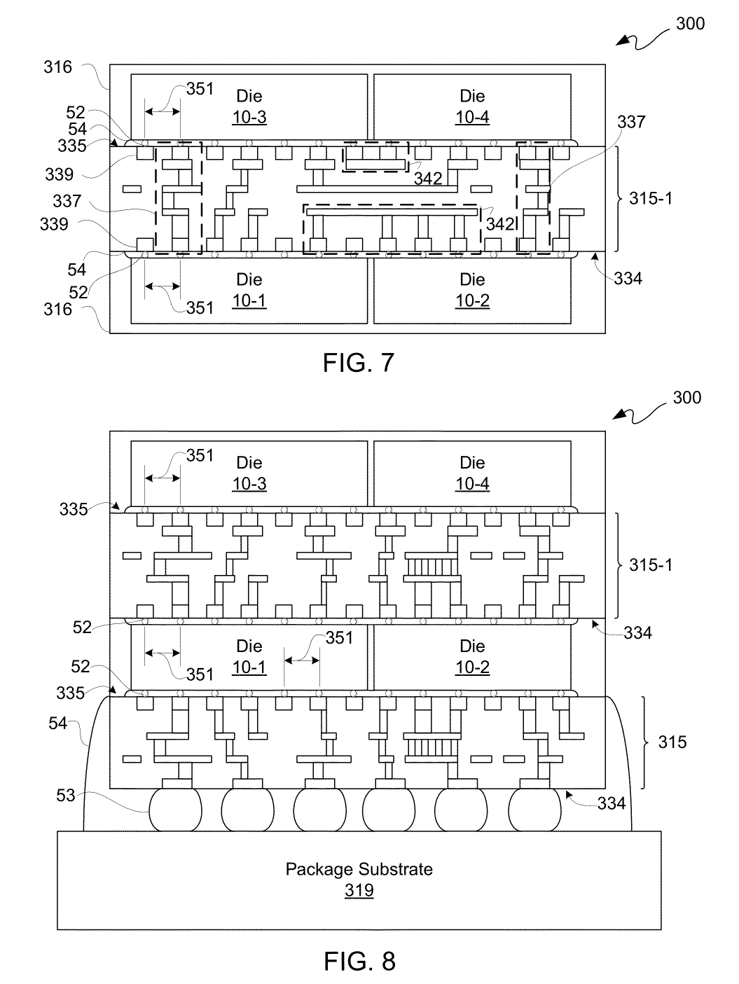

FIG. 8 is a cross-sectional view depicting a 3D stacked IC device 300 including a dual-sided die attachment BEOL stack 315-1 of FIG. 7. In this configuration, a BEOL stack 315, such as previously described with reference to FIG. 3-1 through 3-8 for example, has integrated circuit dies 10-1 and 10-2 coupled to integrated circuit dies 10-3 and 10-4 through BEOL stack 315-1 as in FIG. 7. In this configuration integrated circuit dies 10-1 and 10-2 may include through die vias, such as previously described herein, for interconnection of microbumps 52 along an upper surface 335 of BEOL stack 315 to microbumps 52 along a lower surface 334 of BEOL stack 315-1.

While the foregoing describes exemplary embodiment(s) in accordance with one or more aspects of the invention, other and further embodiment(s) in accordance with the one or more aspects of the invention may be devised without departing from the scope thereof, which is determined by the claim(s) that follow and equivalents thereof. Claim(s) listing steps do not imply any order of the steps. Trademarks are the property of their respective owners.

1. An apparatus, comprising:
a back-end-of-line (“BEOL”) stack configured to electrically couple at least one first electrical component to at least one second electrical component, the BEOL stack not including a substrate;
first contacts provided on a first side of the BEOL stack with a first pitch for providing a bondable surface for connection to the at least one first electrical component; and
second contacts provided on a second side of the BEOL stack with a second pitch larger than the first pitch, the second contacts providing another bondable surface for connection to the at least one second electrical component.

2. The apparatus according to claim 1, wherein:
the BEOL stack includes dielectric layers and conductive layers; and
the conductive layers of the BEOL stack extend horizontally and vertically through the dielectric layers of the BEOL stack formed by dielectric and metal depositions.

3. The apparatus according to claim 2, wherein the conductive layers are interconnected to one another to provide electrically conductive paths at least a portion of which are from at least a first portion of the first contacts on the first side of the BEOL stack to at least a portion of the second contacts on the second side of the BEOL stack.

4. The apparatus according to claim 3, wherein:
the electrically conductive paths are to interconnect the at least one first electrical component via the first portion of the contacts to the first side of the BEOL stack; and
the electrically conductive paths are to interconnect the at least one second electrical component via the portion of the second contacts to the second side of the BEOL stack.

5. The apparatus according to claim 4, wherein:
the electrically conductive paths are first electrically conductive paths; and
the conductive layers are further interconnected to one another to provide second electrically conductive paths from a second portion of the first contacts on the first side of the BEOL stack to a third portion of the first contacts on the first side of the BEOL stack for interconnection of the at least one first electrical component and the at least one second electrical component to one another via the second portion and the third portion of the first contacts.

6. The apparatus according to claim 1, wherein the first pitch of the first contacts is less than 100 microns.

7. The apparatus according to claim 1, wherein the second pitch of the second contacts is greater than 50 microns and less than 500 microns.

8. An apparatus, comprising:
a back-end-of-line (“BEOL”) stack configured to electrically couple at least one first electrical component to at least one second electrical component, the BEOL stack not including a substrate;
first contacts provided on a first side of the BEOL stack with a first pitch for providing a bondable surface for connection to the at least one first electrical component; and
second contacts provided on a second side of the BEOL stack with a second pitch for providing another bondable surface for connection to the at least one second electrical component;
wherein both the first pitch and the second pitch are fine pitches for interconnection with the at least one first electrical component and the at least one second electrical component, respectively.

9. The apparatus according to claim 8, wherein both the first pitch and the second pitch are less than approximately 60 microns.

10. The apparatus according to claim 9, wherein:
the BEOL stack includes dielectric layers and conductive layers; and
the conductive layers of the BEOL stack extend horizontally and vertically through the dielectric layers of the BEOL stack formed with back-end-of-line dielectric and metal depositions.

11. The apparatus according to claim 10, wherein the conductive layers are interconnected to one another to provide electrically conductive paths at least a portion of which are from at least a first portion of the first contacts on the first side of the BEOL stack to at least a first portion of the second contacts on the second side of the BEOL stack.

12. The apparatus according to claim 11, wherein:
the electrically conductive paths are to interconnect the at least one first electrical component via the first portion of the contacts to the first side of the BEOL stack; and
the electrically conductive paths are to interconnect the at least one second electrical component via the first portion of the second contacts to the second side of the BEOL stack;
wherein the apparatus further comprises:
a first underfill layer between the first side of the BEOL stack and the at least one first electrical component; and
a second underfill layer between the second side of the BEOL stack and the at least one second electrical component.

13. The apparatus according to claim 12, wherein:
the electrically conductive paths are first electrically conductive paths; and
the conductive layers are further interconnected to one another to provide second electrically conductive paths from a second portion of the first contacts on the first side of the BEOL stack to a third portion of the first contacts on the first side of the BEOL stack for interconnection of the at least one first electrical component and the at least one second electrical component to one another via the second portion and the third portion of the first contacts.

14. A method, comprising:
forming a back-end-of-line (“BEOL”) stack formed using a temporary support structure;
wherein the forming comprises:
depositing dielectric layers and conductive layers with back-end-of-line dielectric and metal depositions;
wherein the conductive layers of the BEOL stack extend horizontally and vertically through the dielectric layers of the BEOL stack formed to provide electrically conductive paths;
wherein the BEOL stack includes:
first contacts of the conductive layers provided on a first side of the BEOL stack with a first pitch; and
second contacts of the conductive layers provided on a second side of the BEOL stack with a second pitch; and
removing the temporary support structure after formation of the BEOL stack, wherein the BEOL stack does not include a substrate.

15. The method according to claim 14, further comprising:
providing first interconnects for the first contacts; and
coupling at least one first electrical component to the first side of the BEOL stack using the first interconnects and the first contacts.

16. The method according to claim 15, wherein the step of removing the temporary support structure is performed after the step of coupling.

17. The method according to claim 16, wherein the first pitch of the first contacts is less than 100 microns.

18. The method according to claim 17, further comprising:
providing second interconnects for the second contacts; and
coupling a circuit platform to the second side of the BEOL stack using the second interconnects and the second contacts;
wherein the second pitch of the second contacts is greater than 50 microns and less than 500 microns.

19. The method according to claim 17, further comprising:
providing second interconnects for the second contacts; and
coupling at least one second electrical component to the second side of the BEOL stack using the second interconnects and the second contacts;
wherein the second pitch is less than approximately 60 microns.

20. The method according to claim 19, further comprising:
forming third interconnects on a surface of the at least one second electrical component;
wherein the surface is opposite the second side of the BEOL stack.
